(19) United States
(12) Patent Application Publication
(10) Pub. No.: US 2026/0101598 A1
(43) Pub. Date: Apr. 9, 2026

(54) IMAGE SENSING DEVICE

(71) Applicant: SK hynix Inc., Icheon-si (KR)

(72) Inventors: Woo Yung JUNG, Icheon-si (KR); Hyun Soo CHO, Icheon-si (KR)

(21) Appl. No.: 19/319,393

(22) Filed: Sep. 4, 2025

(30) Foreign Application Priority Data
Oct. 8, 2024 (KR) 10-2024-0136916

(51) Int. Cl. H10F 39/00

(52) U.S. Cl. CPC H10F 39/8053; H10F 39/804

(57) ABSTRACT

An image sensing device includes: a semiconductor substrate including photoelectric conversion elements configured to generate photocharges in response to incident light, and a pixel isolation structure disposed between the photoelectric conversion elements; a plurality of color filters disposed on the semiconductor substrate; and a grid structure disposed between adjacent color filters of the color filters to prevent or reduce optical crosstalk between adjacent color filters. The grid structure includes: an air layer; a first capping layer at least partially surrounding the air layer and including a plurality of first holes; and a second capping layer disposed along a surface of the first capping layer and filling some of the first holes.

### CROSS-REFERENCE TO RELATED APPLICATION

This patent document claims the priority and benefits of Korean patent application No. 10-2024-0136916, filed on Oct. 8, 2024, which is incorporated by reference in its entirety as part of the disclosure of this patent document.

### TECHNICAL FIELD

The technology and implementations disclosed in this patent document generally relate to an image sensing device.

### BACKGROUND

An image sensor is a device that captures optical images by converting light into electrical signals using a photosensitive semiconductor material that reacts to light. With the recent advancements in the computer and communication industries, the demand for high-performance image sensors is growing across various fields, such as digital cameras, camcorders, personal communication systems (PCSs), game consoles, robots, surveillance cameras, medical micro cameras, etc.

### SUMMARY

Various embodiments of the disclosed technology relate to an image sensing device designed to improve the stability of a grid structure that includes an air layer.

In an embodiment of the disclosed technology, an image sensing device may include: a semiconductor substrate including photoelectric conversion elements configured to generate photocharges in response to incident light, and a pixel isolation structure disposed between the photoelectric conversion elements; a plurality of color filters disposed on the semiconductor substrate; and a grid structure disposed between adjacent color filters of the color filters to prevent optical crosstalk between adjacent color filters. The grid structure includes: an air layer; a first capping layer at least partially surrounding the air layer and including a plurality of first holes; and a second capping layer disposed along a surface of the first capping layer and filling some of the first holes.

In another embodiment of the disclosed technology, an image sensing device may include an effective pixel region including a plurality of effective pixels configured to detect incident light and to generate actual image data from the detected incident light; a dummy pixel region located outside the effective pixel region and including a plurality of dummy pixels configured to perform one or more functions other than generating the actual image data or perform no function; a plurality of color filters located in correspondence to the effective pixels and the dummy pixels to filter light incident; and a grid structure disposed between adjacent color filters of the plurality of color filters in each of the effective pixel region and the dummy pixel region. The grid structure includes: an air layer; a first capping layer at least partially covering the air layer and including a plurality of first holes; and a second capping layer configured to fill the first holes in the effective pixel region.

It is to be understood that both the foregoing general description and the following detailed description of the disclosed technology are illustrative and explanatory, providing further explanation of the disclosed technology.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device based on some implementations of the disclosed technology.

FIG. 2 is a plan view illustrating an example of the appearance of a grid structure formed in a pixel region shown in FIG. 1 based on some implementations of the disclosed technology.

FIG. 3 is a cross-sectional view illustrating an example of a cross-section of the grid structure taken along the line X-X′ shown in FIG. 2 based on some implementations of the disclosed technology.

FIGS. 4 to 15 are cross-sectional views illustrating examples of a method for forming the grid structure shown in FIG. 3 based on some implementations of the disclosed technology.

### DETAILED DESCRIPTION

This patent document provides implementations and examples of an image sensing device that may be used to substantially address one or more technical or engineering issues and mitigate limitations or disadvantages encountered in some other image sensing devices. The disclosed technology can be implemented in some embodiments to provide an image sensing device that can improve the stability of a grid structure that includes an air layer.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

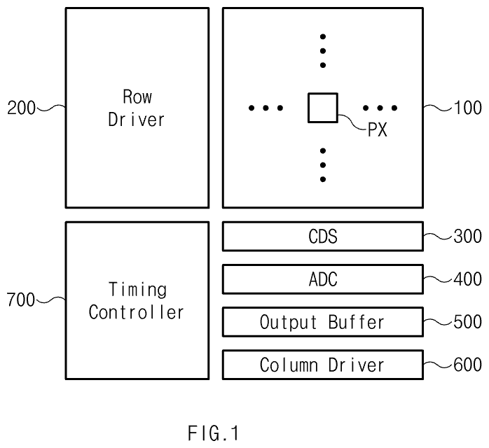

FIG. 1 is a block diagram illustrating an example of an image sensing device based on some implementations of the disclosed technology.

Referring to FIG. 1, the image sensing device may include a pixel region 100, a row driver 200, a correlated double sampler (CDS) 300, an analog-to-digital converter (ADC) 400, an output buffer 500, a column driver 600, and a timing controller 700. The components of the image sensing device illustrated in FIG. 1 are discussed by way of example only, and this patent document encompasses numerous other changes, substitutions, variations, alterations, and modifications. In this patent document, the word “pixel” can be used to indicate an image sensing pixel that is structured to detect incident light to generate electrical signals carrying images in the incident light.

The pixel region 100 may include a plurality of unit pixels (PXs) consecutively arranged in a two-dimensional (2D) structure. The unit pixels (PXs) may convert incident light into electrical signals corresponding to the incident light, may generate pixel signals, and may output the pixel signals to the CDS 300 through column lines. The pixel region 100 may include a grid structure to prevent crosstalk between color filters of adjacent unit pixels. The grid structure may include a structure in which an air layer is capped by a capping layer. In particular, the grid structure may include a structure to prevent collapse of the capping layer due to expansion of the air layer. For example, the grid structure may include a plurality of through-holes formed to penetrate an upper surface of the capping layer in some areas of the pixel array.

The pixel region 100 may receive driving signals (for example, a row selection signal, a reset signal, a transfer signal, etc.) from the row driver 200. Upon receiving the driving signals, the unit pixels may be activated to perform the operations corresponding to the row selection signal, the reset signal, and the transfer signal.

The row driver 200 may activate the unit pixels based on control signals received from controller circuitry such as the timing controller 700. In some implementations, the row driver 200 may select one or more unit pixels arranged in one or more rows of the pixel region 100. The row driver 200 may generate a row selection signal to select one or more rows from among the plurality of rows. The row driver 200 may sequentially enable the reset signal and the transfer signal for the unit pixels arranged in the selected row. The pixel signals generated by the unit pixels arranged in the selected row may be output to the correlated double sampler (CDS) 300.

The correlated double sampler (CDS) 300 may remove undesired offset values of the unit pixels using correlated double sampling. In one example, the correlated double sampler (CDS) 300 may remove the undesired offset values of the unit pixels by comparing output voltages of pixel signals (of the unit pixels) obtained before and after photocharges generated by incident light are accumulated in the sensing node (i.e., a floating diffusion (FD) node).

The ADC 400 may convert the CDS signal received from the correlated double sampler (CDS) 300 into a digital signal.

The output buffer 500 may temporarily store column-based data received from the ADC 400 under the control of the timing controller 700.

The column driver 600 may select a column of the output buffer 500 under the control of the timing controller 700, and may sequentially output data temporarily stored in the selected column of the output buffer 500.

The timing controller 700 may generate signals for controlling operations of the row driver 200, the ADC 400, the output buffer 500 and the column driver 600. The timing controller 700 may provide the row driver 200, the column driver 600, the ADC 400, and the output buffer 500 with a clock signal required for the operations of the respective components of the image sensing device, a control signal for timing control, and address signals for selecting a row or column.

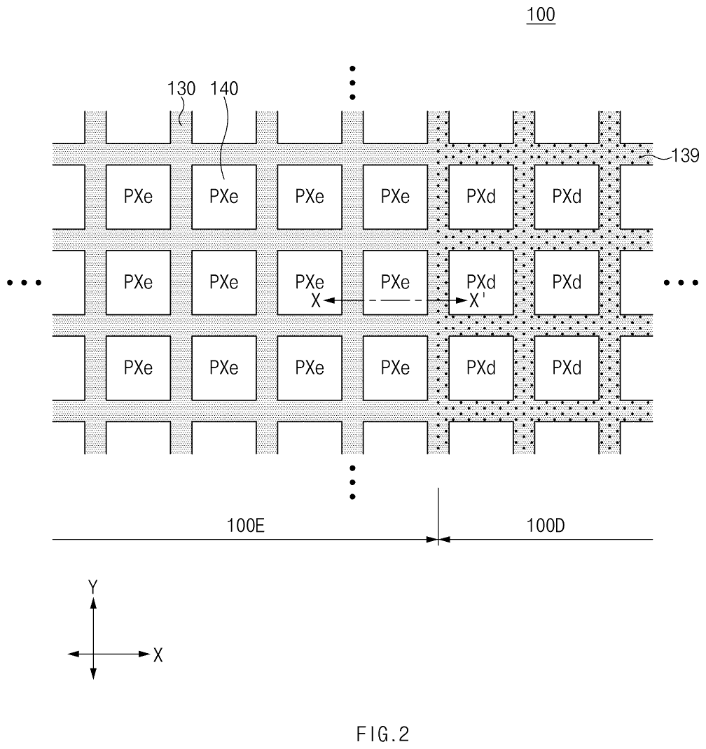

FIG. 2 is a plan view illustrating an example of the appearance of the grid structure formed in the pixel region 100 shown in FIG. 1 based on some implementations of the disclosed technology.

Referring to FIG. 2, the pixel region 100 may include an effective pixel region 100E and a dummy pixel region 100D. In some embodiments, the effective pixel region 100E includes effective pixels that detect incident light to produce effective pixel signals that are used as actual image data whereas the dummy pixel region 100D includes dummy pixels that similarly or identically structured as the effective pixels but are not directly used for generating image data. In one example, the dummy pixels can be utilized for other purposes such as calibration, stabilization, correction, etc. in connection with the image data. In another example, the dummy pixels may not be used to perform any function. The effective pixel region 100E may be formed in a square shape at the center of the image sensing device. The dummy pixel region 100D may be formed outside the effective pixel region 100E while being adjacent to the effective pixel region 100E. For example, the dummy pixel region 100D may be formed in a square frame shape surrounding the effective pixel region 100E.

The effective pixel region 100E may include effective pixels (PXe) that are arranged consecutively in a first direction (e.g., X-axis direction) and a second direction (e.g., Y-axis direction) perpendicular to the first direction. Effective pixels (PXe) may refer to pixels for image generation.

The dummy pixel region 100D may include dummy pixels (PXd) arranged consecutively in the first direction and the second direction. In some implementations, the dummy pixels (PXd) may have the same structure as the effective pixels (PXe). In some implementations, the dummy pixels (PXd) may refer to pixels that are not used for image generation.

The effective pixels (PXe) and the dummy pixels (PXd) may include a color filter 140 to filter incident light to transmit light at a particular color while blocking light in other colors. The pixel region 100 may include a grid structure 130 disposed between color filters 140 (PXs) of the adjacent pixels (PXe, PXd) to prevent or reduce optical crosstalk between the adjacent color filters 140. In some implementations, the color filters 140 may be arranged in certain color patterns to enable the effective pixels to capture color information in an image carried by the incident light such as a Bayer pattern for the color filters 140.

The grid structure 130 may include a plurality of first portions extending across the effective pixel region 100E and the dummy pixel region 100D in a first direction between the color filters 140, and a plurality of second portions extending across the effective pixel region 100E and the dummy pixel region 100D in a second direction between the color filters 140. The first portions and the second portions may be formed to cross each other and surround each of the color filters 140. For example, the color filters 140 may be formed in a region defined by the plurality of first portions and the plurality of second portions.

The grid structure 130 may include an air layer and a capping layer that covers the air layer. The capping layer may include a multilayer structure in which a plurality of insulation layers is formed to overlap each other. The capping layer may include an ultra-low-temperature oxide (ULTO) layer such as a silicon oxide (SiO₂) layer.

The grid structure 130 may include through-holes selectively formed only in some areas of the pixel region 100. For example, the grid structure 130 may include a plurality of through-holes 139 formed to penetrate the upper portion of the capping layer in the dummy pixel region 100D. The through-holes 139 may prevent or minimize pressure differences between the inside and the outside of the grid structure 130, thereby avoiding expansion of the air layer in the grid structure 130.

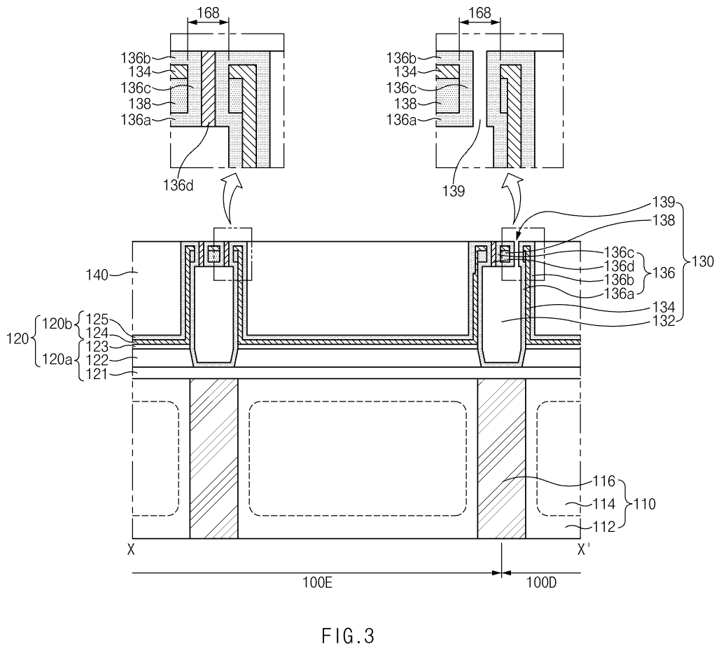

FIG. 3 is a cross-sectional view illustrating an example of a cross-section of the grid structure taken along the line X-X′ shown in FIG. 2 based on some implementations of the disclosed technology.

Referring to FIG. 3, the pixel region 100 of the image sensing device may include a substrate layer 110, a buffer layer 120, a grid structure 130, and a plurality of color filters 140.

The substrate layer 110 may include a substrate 112, photoelectric conversion elements 114, and a pixel isolation structure 116.

The substrate 112 may include a semiconductor substrate having a first surface and a second surface facing or opposite to the first surface. In some implementations, the first surface is a surface upon which light is incident, and the buffer layer 120, the grid structure 130, and the color filters 140 may be formed thereon. In some implementations, the semiconductor substrate 112 may be in a monocrystalline state, and may include a silicon-containing material. In one example, the semiconductor substrate 112 may include a monocrystalline silicon-containing material. The semiconductor substrate 112 may include P-type impurities. The photoelectric conversion elements 114 and the pixel isolation structures 116 may be formed in the semiconductor substrate 112. The semiconductor substrate 112 may include an effective pixel region 100E and a dummy pixel region 100D.

The photoelectric conversion elements 114 may perform conversion of incident light received through the first surface of the semiconductor substrate 112, resulting in the generation of photocharges. In some implementations, the photoelectric conversion elements 114 may be formed in the semiconductor substrate 112 to respectively correspond to the effective pixels (PXe) and the dummy pixels (PXd). In one example, each of the photoelectric conversion elements 114 may be formed for each unit pixel (PX) in the semiconductor substrate 112. The photoelectric conversion elements 114 may be isolated from each other by the pixel isolation structure 116. Each photoelectric conversion element 114 may include impurity regions stacked vertically within the semiconductor substrate 112. For example, each photoelectric conversion element 114 may include a photodiode in which an N-type impurity region and a P-type impurity region are stacked in a vertical direction.

The pixel isolation structure 116 may be formed between adjacent photoelectric conversion elements 114 within the semiconductor substrate 112 so that the photoelectric conversion elements 114 can be isolated from each other for each pixel. The pixel isolation structure 116 may include a trench structure such as Back Deep Trench Isolation (BDTI) or Front Deep Trench Isolation (FDTI). Alternatively, the pixel isolation structure 116 may include a junction isolation structure in which a high concentration of impurities (e.g., P-type impurities) is implanted into the semiconductor substrate 112.

The buffer layer 120 may be disposed between the semiconductor substrate 112 and the color filters 140 over the first surface of the semiconductor substrate 112. The buffer layer 120 may operate as a planarization layer, smoothing out any step differences formed on the first surface of the semiconductor substrate 112. In addition, the buffer layer 120 may operate as an anti-reflection layer to allow incident light to pass through the photoelectric conversion elements 114.

The buffer layer 120 may include a multilayer structure formed by stacking an oxide layer and a nitride layer. For example, the buffer layer 120 may include a lower buffer layer 120a and an upper buffer layer 120b.

The lower buffer layer 120a may be disposed under the grid structure 130 and the color filters 140 over the substrate layer 110. The lower buffer layer 120a may include first to third buffer layers (121, 122, 123). The first buffer layer 121 may include a metal oxide layer such as aluminum oxide (Al₂O₃) or hafnium oxide (HfO₂). The second buffer layer 122 may include a silicon oxide (SiO₂) layer, and the third buffer layer 123 may include a nitride layer such as a silicon nitride layer or a silicon oxynitride layer.

The upper buffer layer 120b may be formed between the lower buffer layer 120a and the color filters 140. The upper buffer layer 120b may include a fourth buffer layer 124 and a fifth buffer layer 125. The fourth buffer layer 124 may be formed of the same material as the first capping layer 134 of the grid structure 130, and may be formed together with the first capping layer 134 through the same deposition process. The fifth buffer layer 125 may be formed of the same material as the second capping layer 136 of the grid structure 130, and may be formed together with the second capping layer 136 through the same deposition process. For example, the fourth buffer layer 124 and the fifth buffer layer 125 may be formed such that the first capping layer 134 and the second capping layer 136 extend below the color filter 140. The fourth buffer layer 124 and the fifth buffer layer 125 may include an ultra-low-temperature oxide (ULTO) layer.

The grid structure 130 may be located between the color filters 140 to prevent or reduce optical crosstalk between adjacent color filters. The grid structure 130 may be disposed to overlap the pixel isolation structure 116. Each of the grid structures 130 may include an air layer 132, a first capping layer 134, a second capping layer 136, a support layer 138, and a through-hole 139.

The air layer 132 may be formed in a region defined by the first capping layer 134 and the second capping layer 136. The air layer 132 may extend downward to the inside of the lower buffer layer 120a.

The first capping layer 134 and the second capping layer 136 may cap the air layer 132. The first capping layer 134 may be disposed in the second capping layer 136. For example, the first capping layer 134 and the second capping layer 136 may be formed in a structure in which the second capping layer 136 is stacked over the inner surface and the outer surface of the first capping layer 134 to entirely surround the first capping layer 134.

The upper region of the first capping layer 134 may be penetrated by first holes 168. The first holes 168 may be formed in the effective pixel region 100E and the dummy pixel region 100D. The first holes 168 may be formed using a direct self-assembly process of a block copolymer.

Some of the first holes 168 may be fully filled, while others may be partially filled. For example, in the grid structure 130 of the effective pixel region 100E, the first holes 168 may be fully filled with the second capping layer 136, and in the grid structure 130 of the dummy pixel region 100D, the first holes 168 may be partially filled with the second capping layer 136, so that each of the through-holes 139 may be formed inside each of the first holes 168.

The second capping layer 136 may include an inner capping layer 136a, an outer capping layer 136b, a connection capping layer 136c, and a buried capping layer 136d. The inner capping layer 136a may be formed to cover the inner surface of the first capping layer 134. The inner capping layer 136a may be formed to contact the air layer 132. The outer capping layer 136b may be formed to cover the outer surface of the first capping layer 134. The outer capping layer 136b may be located at the outermost portion of the grid structure 130. The connection capping layer 136c may cover the side surface of the first holes 168, and may be connected to the inner capping layer 136a and the outer capping layer 136b. In each of the first holes 168, an empty space in which the buried capping layer 136d is not formed may be used as the through-hole 139. The buried capping layer 136d may be located only in the effective pixel region 100E from among the effective pixel region 100E and the dummy pixel region 100D, thereby filling the through-holes 139. The through-holes 139 formed in the dummy pixel region 100D may prevent the air layer 132 from expanding by preventing occurrence of a pressure difference between the inside and the outside of the grid structure 130.

Although the above-discussed example specifies that the second capping layer 136 is divided into several regions (136a-136d) for convenience of description, other implementations are also possible, and it should be noted that the inner capping layer 136a, the outer capping layer 136b, and the connection capping layer 136c may be formed simultaneously through the same deposition process. For example, when the outer capping layer 136b is formed, a material corresponding to the connection capping layer 136c and a material corresponding to the inner capping layer 136a are introduced into the grid structure 130 through the first holes 168, so that the connection capping layer 136c can be formed on the side surfaces of the first holes 168 and the inner capping layer 136a can be formed inside the first capping layer 134. In some implementations, the connection capping layer 136c may be formed to have a thickness smaller than 1/2 of a diameter of the first hole 168, so that the first hole 168 is not filled with the connection capping layer 136c and the through-hole 139 is formed. Each of the inner capping layer 136a and the outer capping layer 136b may be formed to have the same thickness as the connection capping layer 136c.

Each of the first capping layer 134 and the second capping layer 136 may include an ultra-low-temperature oxide (ULTO) layer. Alternatively, the first capping layer 134 may include an ultra-low-temperature oxide (ULTO) layer, and the second capping layer 136 may include a material layer different from the first capping layer 134. For example, the second capping layer 136 may include at least one of an aluminum oxide (Al₂O₃) layer, a hafnium oxide (HfO₂) layer, and a silicon nitride (SiN) layer.

The support layer 138 may be disposed over the lower surface of the first capping layer 134 in the upper region of the grid structure 130. The support layer 138 may support the first capping layer 134 to prevent the first capping layer 134 from collapsing while the air layer 132 is formed. The support layer 138 may include an insulation layer having no light absorption characteristics. For example, the support layer 138 may be an insulation layer with a different etch selectivity from a spin on carbon (SOC) layer containing carbon, and may include a silicon oxynitride (SiON) layer. An upper region of the support layer 138 may also be penetrated by the first holes 168. The support layer 138 may not be formed as needed.

The air layer 132 and the inner capping layer 136a may extend downward to a position lower than the bottom surface of the first capping layer 134. For example, the air layer 132 and the inner capping layer 136a may extend to the inside of the lower buffer layer 120a. In this way, since the air layer 132 is formed to extend to a deep depth, incident light may be prevented from generating crosstalk through the lower buffer layer 120a. Although FIG. 3 shows that the air layer 132 extends to the inside of the second buffer layer 122, the air layer 132 may also be formed to extend either to the inside of the first buffer layer 121 or to the pixel isolation structure 116.

The color filters 140 may filter light incident through the lens layer 150 depending on colors of the incident light, and may allow the filtered light to pass therethrough. The color filters 140 may be disposed in a region defined by the grid structure 130 on the substrate layer 110. The color filters 140 may be located to correspond to the photoelectric conversion elements 114. The color filters 140 may include a plurality of red color filters, a plurality of green color filters, and a plurality of blue color filters. The color filters 140 may be arranged in a Bayer pattern.

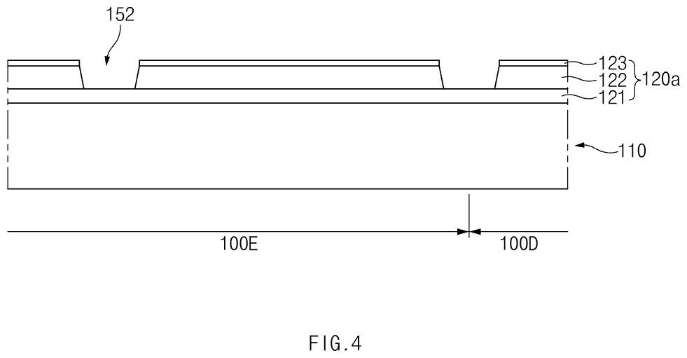

FIGS. 4 to 15 are cross-sectional views illustrating examples of a method for forming the grid structure shown in FIG. 3 based on some implementations of the disclosed technology.

First, referring to FIG. 4, a lower buffer layer 120a may be formed over the substrate layer 110 on which the photoelectric conversion element and the pixel isolation structure are formed within the semiconductor substrate. For example, first to third buffer layers (121, 122, 123) may be sequentially formed on the substrate layer 110. In some implementations, the first buffer layer 121 may include a metal oxide layer such as an aluminum oxide (Al₂O₃) layer or a hafnium oxide (HfO₂) layer. The second buffer layer 122 may include a silicon oxide (SiO₂) layer, and the third buffer layer 123 may include a nitride layer such as a silicon nitride layer or a silicon oxide nitride layer.

Subsequently, a trench 152 in which a region where the grid structure 130 is to be formed in the lower buffer layer 120a is etched to a certain depth may be formed. The trench 152 may be formed to expose the first buffer layer 121. Alternatively, the trench 152 may penetrate the lower buffer layer 120a and may be formed to a preset depth such that the pixel isolation structure of the substrate layer 110 is exposed.

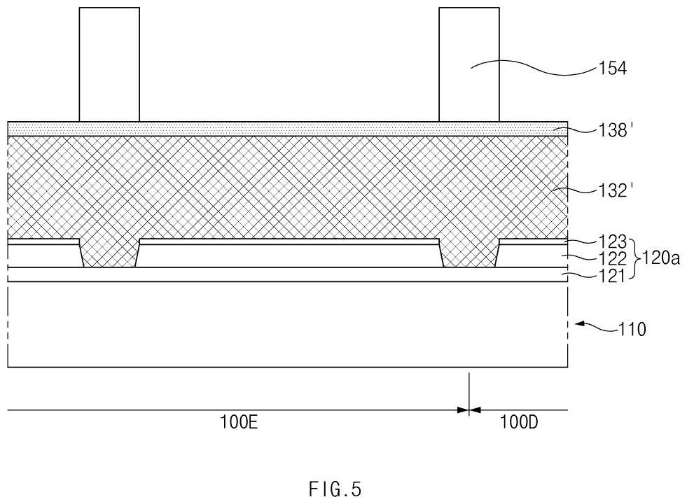

Referring to FIG. 5, a sacrificial layer 132′ may be formed over the lower buffer layer 120a in which the trench 152 is formed, and a support material layer 138′ may be formed over the sacrificial layer 132′. In some implementations, the sacrificial layer 132′ may include a SOC (Spin On Carbon) layer containing carbon, and the support material layer 138′ may include a silicon oxynitride (SiON) layer.

Subsequently, a mask pattern 154 defining a region to be capped by the first capping layer 134 may be formed over the support material layer 138′. For example, a mask pattern 154 defining a region where the inner capping layer 136a and the air layer 132 of FIG. 3 are to be formed may be formed over the support material layer 138′. The mask pattern 154 may include a photoresist pattern.

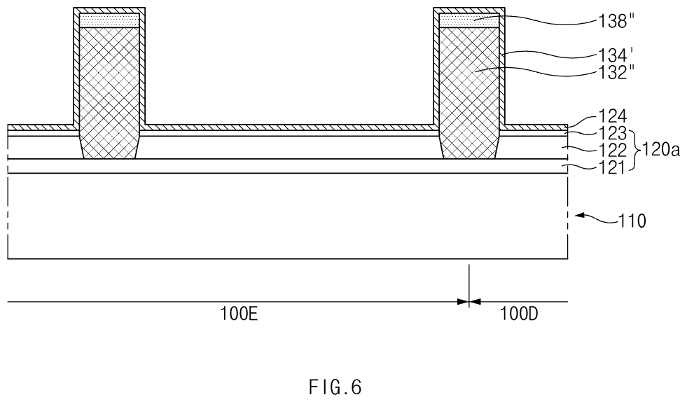

Referring to FIG. 6, the support material layer 138′ and the sacrificial layer 132′ may be sequentially etched using the mask pattern 154 as an etching mask, thereby forming a support layer pattern 138″ and a sacrificial layer pattern 132″.

Subsequently, the insulation layers (124, 134′) may be formed to cover the lower buffer layer 120a, the sacrificial layer pattern 132″, and the support layer pattern 138″. The insulation layer (124, 134′) may include an ultra-low-temperature oxide (ULTO) layer. Although the present embodiment has disclosed that the insulation layers (124, 134′) are shown as different layers for convenience of description, the insulation layers (124, 134′) may be formed simultaneously through the same process.

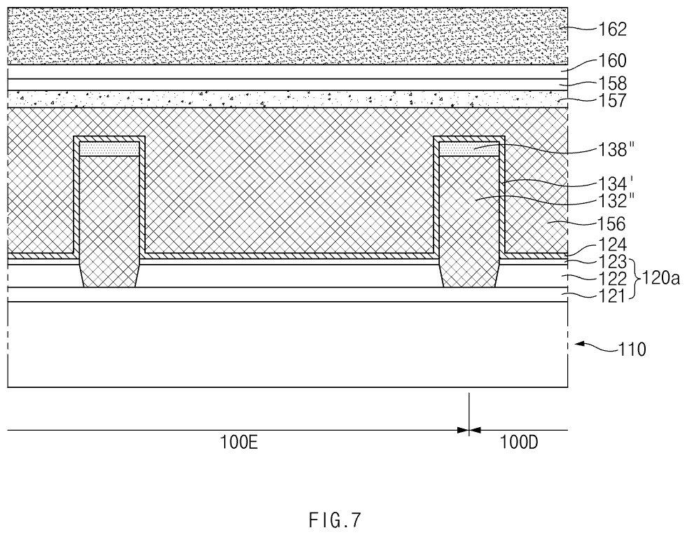

Referring to FIG. 7, insulation layers (156, 157, 158) may be sequentially formed over the insulation layers (124, 134′). In some implementations, the insulation layer 156 may include a carbon-containing SOC (Spin On Carbon) layer, and the insulation layer 157 may include a silicon oxide nitride (SiON) layer. The insulation layer 158 may include a polysilicon layer.

Thereafter, a neutral layer 160 and a direct self-assembly (DSA) material layer 162 may be sequentially formed over the insulation layer 158.

The neutral layer 160 may induce pattern formation of the DSA material layer 162. The neutral layer 160 may serve to induce polymer blocks forming a block copolymer to be phase-separated into block domain portions that are alternately repeated in a cylinder shape or a lamellar shape. The neutral layer 160 may operate as an orientation control layer that controls orientation of the polymer blocks during the phase separation process in which the polymer blocks are re-ordered to form block domain portions, thereby causing the block domain portions to be alternately repeated.

The neutral layer 160 may be formed of a material having a similar affinity for each of the polymer block components forming the block copolymer. For example, the neutral layer 160 may include a random copolymer in which different polymer components forming the block copolymer are randomly copolymerized. When a polystyrene-polymethyl methacrylate block copolymer (PS-b-PMMA) is used as a self-aligned block copolymer, the neutral layer 160 may include a random copolymer of polystyrene and polymethyl methacrylate (PS-b-PMMA) (i.e., random PS: PMMA (PS-r-PMMA)).

The DSA material layer 162 may include a block copolymer in which two or more types of polymer blocks having different structures are covalently bonded to form one polymer. For example, the DSA material layer 162 may include polymethyl methacrylate (PMMA) and polystyrene (PS). The DSA material layer 162 may be coated in a homogeneous phase mixed state using a spin coating method.

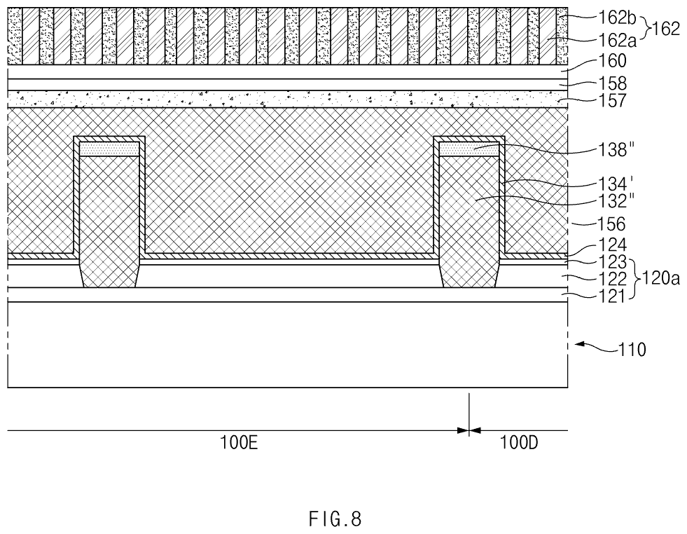

Referring to FIG. 8, DSA patterning may be performed on the DSA material layer 162. For example, an N₂ annealing process may be performed on the DSA material layer 162.

The DSA material layer 162 may be phase-separated into a first polymer block component 162a and a second polymer block component 162b by the annealing process. When the DSA material layer 162 includes a block copolymer, the DSA material layer 162 may be separated into PMMA (polymethyl methacrylate) and PS (polystyrene) by the annealing process. PMMA and PS may be self-aligned in various forms depending on a composition ratio.

The polymer block components that constitute the block copolymer may have different mixing characteristics and different solubilities due to differences in chemical structures. The polymer components may be immiscibly separated from each other while being intermixed by annealing, and may be reordered, so that the polymer components can be phase-separated from each other.

Forming a microstructure of a specific shape through direct self-assembly of the block copolymer may be affected by physical and/or chemical characteristics of each block polymer. When a block copolymer composed of two different polymers is self-assembled, the self-assembled structure of the block copolymer may be formed in various structures, such as a three-dimensional (3D) cubic and double helix structure, or a two-dimensional (2D) hexagonal packed column structure and a lamellar structure, depending on a volume ratio of each polymer block that constitutes the block copolymer, the annealing temperature for phase separation, the size of a molecule of the block polymer, and others.

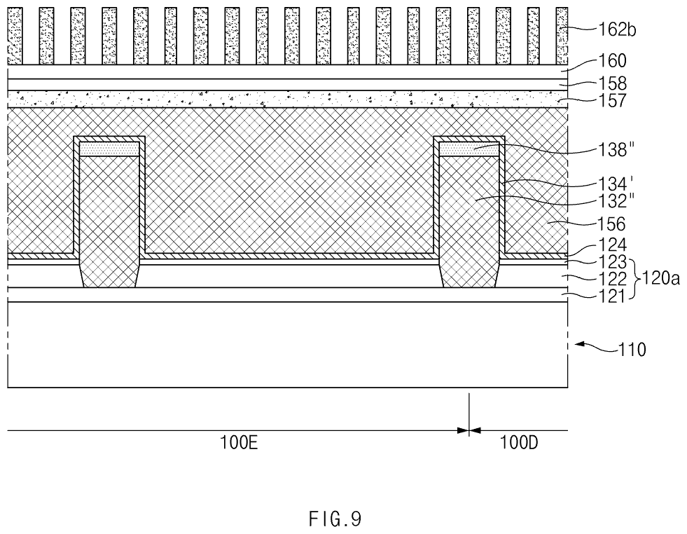

Referring to FIG. 9, the first polymer block component 162a may be selectively removed from the DSA material layer 162 separated into the first polymer block component 162a and the second polymer block component 162b.

For example, a metal-containing precursor may be injected into the DSA material layer 162 so that the metal-containing precursor can be selectively coupled (bound) to the first polymer block component 162a. The metal of the metal-containing precursor may include aluminum (Al). The metal-containing precursor may include tetramethylammonium (TMA). For example, TMA may be selectively coupled (bound) to PMMA.

By injecting such a metal-containing precursor, the metal may penetrate into the first polymer block component 162a, so that the first polymer block component 162a may be modified into the metal-containing first polymer block component. The metal-containing first polymer block component may have an etch selectivity with respect to the second polymer block component 162b. The first polymer block component 162a may be selectively removed using the etch selectivity.

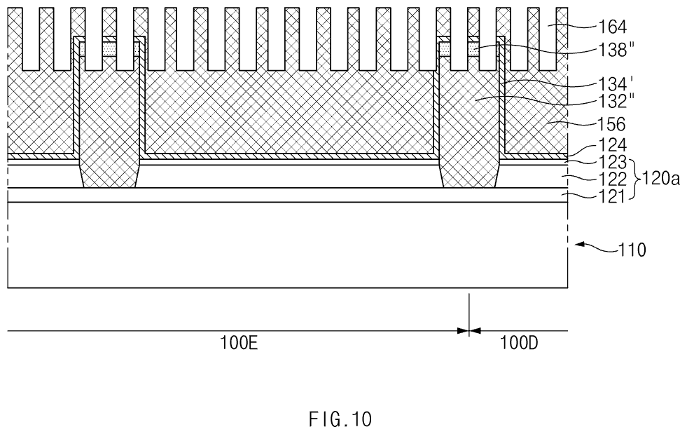

Referring to FIG. 10, a plurality of opening portions 164 may be formed by etching material layers (160, 158, 157, 156, 134′, 138″, 132″) using a DSA pattern including the second polymer block component 162b as an etch mask.

In this case, the plurality of opening portions 164 may allow the sacrificial layer pattern 132″ capped by the insulation layer 134′ to be exposed outside.

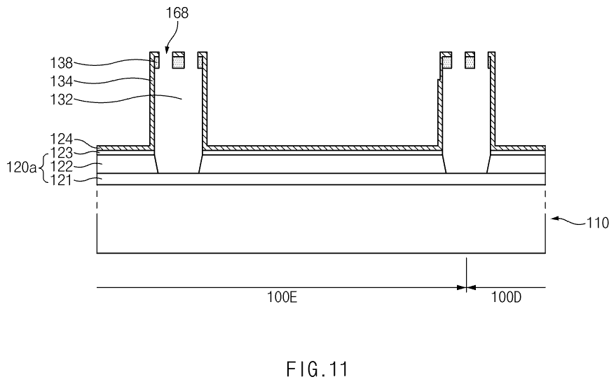

Referring to FIG. 11, the insulation layer 156 and the sacrificial layer pattern 132″ are removed through the plasma process, so that the first capping layer 134 and the support layer 138 penetrated by the first holes 168 are formed, and an air layer 132 may be formed inside the first capping layer 134.

The plasma process may be carried out using gas (e.g., O₂, N₂, H₂, CO, CO₂, or CH₄) including at least one of oxygen, nitrogen, or hydrogen.

For example, if the O₂ plasma process is carried out, oxygen radicals (O*) may flow into the insulation layer 156 and the sacrificial layer pattern 132″, and the oxygen radicals (O*) may be combined with carbons of the insulation layer 156 and the sacrificial layer pattern 132″, resulting in formation of CO or CO₂. As a result, the insulation layer 156 and the sacrificial layer pattern 132″ can be removed. In some implementations, the sacrificial layer pattern 132″ capped by the first capping layer 134 is exposed outside by the plurality of first holes 168, so that the sacrificial layer pattern 132″ may be coupled to the oxygen radicals and thus may be easily removed.

When the plasma process is performed in a state where the sacrificial layer pattern 132″ is completely capped, the oxygen radicals are introduced through the capping layer and are combined with the sacrificial layer pattern 132″, and the generated gases must also escape to the outside through the capping layer, so that the sacrificial layer pattern 132″ is not easily removed. However, as in the present embodiment, if the plasma process is performed with the sacrificial layer pattern 132″ exposed to the outside, the sacrificial layer pattern 132″ may be removed more easily, thereby securing a larger space in which the air layer 132 is formed.

The support layer 138 formed over the sacrificial layer pattern 132″ may prevent the first capping layer 134 from collapsing by supporting the first capping layer 134 while the sacrificial layer pattern 132″ is removed.

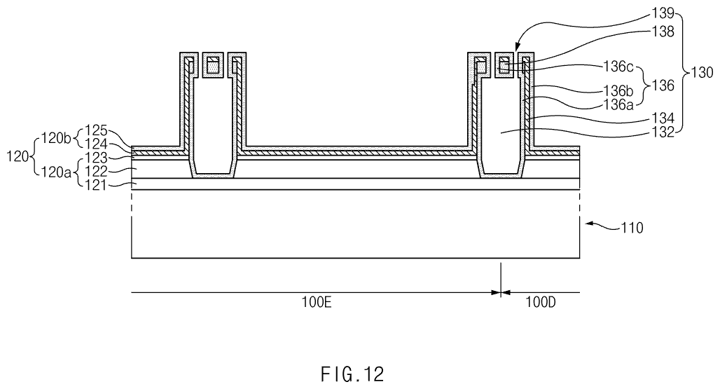

Referring to FIG. 12, the inner capping layer 136a and the outer capping layer 136b of the second capping layer 136 may be formed by depositing an oxide layer on the inner surface and the outer surface of the first capping layer 134. In addition, the connection capping layer 136c may be formed by depositing the oxide layer on the side surface of the first holes 168, and the fifth buffer layer 125 may be formed by depositing the oxide layer on the fourth buffer layer 124.

For example, an ultra-low-temperature oxide (ULTO) layer may be deposited on the inner and outer surfaces of the first capping layer 134, the side surfaces of the first holes 168, and the upper surface of the fourth buffer layer 124 using an atomic layer deposition (ALD) process and/or a chemical vapor deposition (CVD) process. In some implementations, the second capping layer 136 may be formed so that a through-hole 139 exists in the central portion of the first holes 168 without completely filling the first holes 168. For example, the thickness of the connection capping layer 136c may be smaller than half of the diameter of the first hole 168. The inner capping layer 136a, the outer capping layer 136b, and the connection capping layer 136c may be formed to have the same thickness.

The second capping layer 136 may be made of the same material (ULTO) as the first capping layer 134. Alternatively, the second capping layer 136 may be made of a different material from the first capping layer 134. For example, the second capping layer 136 may include an aluminum oxide (Al₂O₃) layer, a hafnium oxide (HfO₂) layer, or a silicon nitride (SiN) layer.

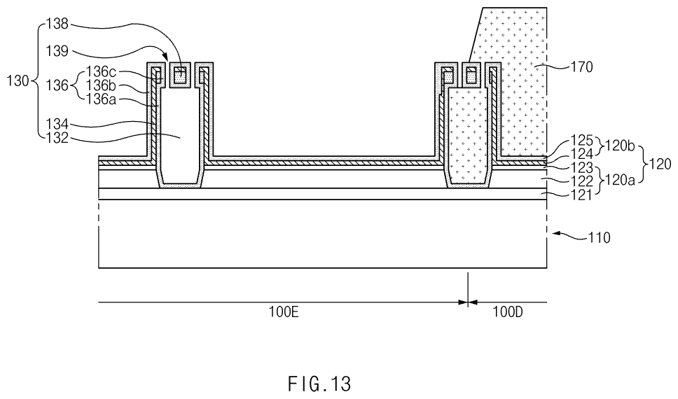

Referring to FIG. 13, a resist layer 170 may be formed in the dummy pixel region 100D so that the effective pixel region 100E is open. That is, the resist layer 170 may be formed so that the through-holes 139 of the effective pixel region 100E are open and the through-holes 139 of the dummy pixel region 100D are covered.

In some implementations, the air layer 132 of the grid structure 130 in a boundary area between the effective pixel region 100E and the dummy pixel region 100D may also be filled with the resist layer 170.

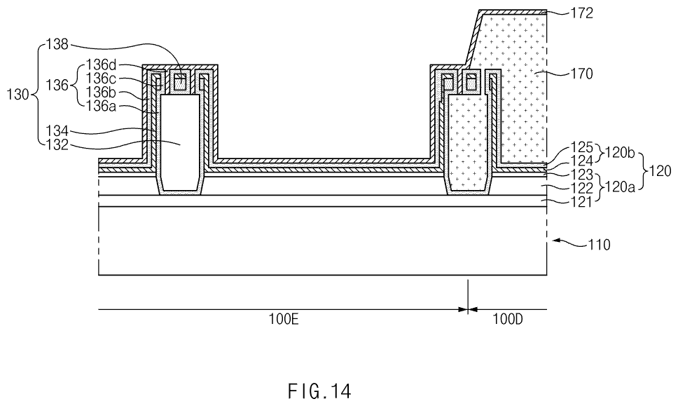

Referring to FIG. 14, the insulation layer 172 may be formed on the fifth buffer layer 125, the grid structure 130, and the resist layer 170 so that the through-holes 139 of the effective pixel region 100E are filled. The insulation layer 172 may include an ultra-low-temperature oxide (ULTO) layer.

In the present embodiment, a portion of the insulation layer 172 buried in the through-holes 139 from among the insulation layer 172 may be used as the buried capping layer 136d of the second capping layer 136.

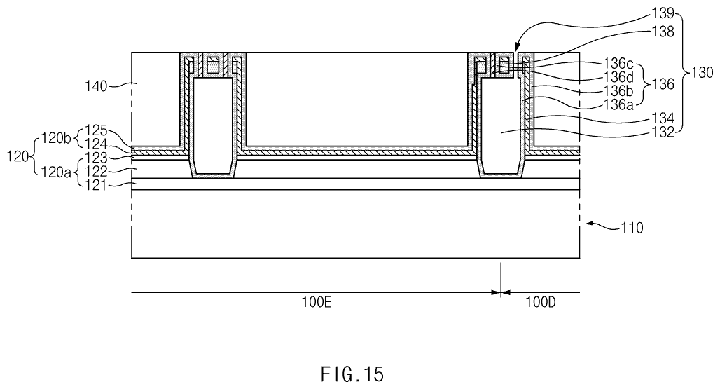

Referring to FIG. 15, the insulation layer 172 may be removed so that the buried capping layer 136d remains.

Subsequently, the resist layer 170 may be removed, opening the through-holes 139 in the dummy pixel region 100D. The grid structure 130 may be formed in an integral grid shape that is connected throughout the pixel region 100, but may have a structure in which the through-holes 139 are selectively formed only in the dummy pixel region 100D.

As described above, since the through-holes 139 are selectively formed only in a portion of the grid structure 130, the air layer 132 remains unsealed and can communicate with the outside through the through-holes 139. Accordingly, no pressure difference arises between the inside and the outside of the grid structure 130, preventing the air layer 132 from expanding during subsequent processes and thereby ensuring the grid structure 130 does not expand.

Subsequently, the color filters 140 may be formed in the region defined by the grid structure 130.

As is apparent from the above description, the image sensing device based on some implementations of the disclosed technology can improve the stability of a grid structure that includes an air layer.

The embodiments of the disclosed technology may provide a variety of effects capable of being directly or indirectly recognized through the above-mentioned patent document.

Although a number of illustrative embodiments have been described, it should be understood that various modifications or enhancements of the disclosed embodiments and other embodiments can be devised based on what is described and/or illustrated in this patent document.

What is claimed is:

1. An image sensing device comprising:
a semiconductor substrate configured to include a pixel region including: photoelectric conversion elements configured to generate photocharges in response to incident light; and a pixel isolation structure disposed between the photoelectric conversion elements;
a plurality of color filters disposed on the semiconductor substrate; and
a grid structure disposed between adjacent color filters of the plurality of color filters to prevent or reduce optical crosstalk between adjacent color filters,
wherein the grid structure includes:
an air layer;
a first capping layer at least partially surrounding the air layer and including a plurality of first holes; and
a second capping layer disposed along a surface of the first capping layer and filling some of the first holes.

2. The image sensing device according to claim 1, wherein:
the first capping layer is surrounded by the second capping layer.

3. The image sensing device according to claim 2, wherein the second capping layer includes:
an inner capping layer disposed inside the first capping layer to cover an inner surface of the first capping layer;
an outer capping layer disposed outside the first capping layer to cover an outer surface of the first capping layer;
a connection capping layer formed on a side surface of the first holes to connect the inner capping layer to the outer capping layer to form one or more through-holes in the first holes; and
a buried capping layer configured to fill a portion of the through-holes.

4. The image sensing device according to claim 3, wherein the pixel region comprises:
a first pixel region including effective pixels configured to generate actual image data; and
a second pixel region located outside the first pixel region and including dummy pixels configured to perform one or more functions other than generating the actual image data or perform no function,
wherein the buried capping layer is disposed only in the first pixel region.

5. The image sensing device according to claim 3, wherein:
the inner capping layer, the outer capping layer, and the connection capping layer have a same thickness.

6. The image sensing device according to claim 3, wherein the grid structure further includes:
a support layer disposed between the first capping layer and the inner capping layer and including the first holes.

7. The image sensing device according to claim 1, wherein:
the first capping layer and the second capping layer include a same material layer.

8. The image sensing device according to claim 7, wherein each of the first capping layer and the second capping layer includes:
an ultra-low-temperature oxide (ULTO) layer.

9. The image sensing device according to claim 1, wherein:
the first capping layer and the second capping layer include different material layers.

10. The image sensing device according to claim 9, wherein:
the first capping layer includes an ultra-low-temperature oxide (ULTO) layer; and
the second capping layer includes at least one of an aluminum oxide (Al₂O₃) layer, a hafnium oxide (HfO₂) layer, or a silicon nitride (SiN) layer.

11. The image sensing device according to claim 1, wherein:
the air layer extends to a position lower than a bottom surface of the first capping layer.

12. An image sensing device comprising:
an effective pixel region including a plurality of effective pixels configured to detect incident light and to generate actual image data from the detected incident light;
a dummy pixel region located outside the effective pixel region and including a plurality of dummy pixels configured to perform one or more functions other than generating the actual image data or perform no function;
a plurality of color filters located in correspondence to the effective pixels and the dummy pixels to filter the incident light; and
a grid structure disposed between adjacent color filters of the plurality of color filters in each of the effective pixel region and the dummy pixel region,
wherein the grid structure includes:
an air layer;
a first capping layer at least partially covering the air layer and including a plurality of first holes; and
a second capping layer configured to fill the first holes in the effective pixel region.

13. The image sensing device according to claim 12, wherein:
the first holes are disposed in an upper region of the first capping layer in both the effective pixel region and the dummy pixel region.

14. The image sensing device according to claim 13, wherein:
the second capping layer is formed to partially fill the first holes in the dummy pixel region to form one or more through-holes in the first holes.

15. The image sensing device according to claim 12, wherein:
the first capping layer is disposed in the second capping layer.

16. The image sensing device according to claim 15, wherein the second capping layer includes:
an inner capping layer disposed inside the first capping layer to cover an inner surface of the first capping layer;
an outer capping layer disposed outside the first capping layer to cover an outer surface of the first capping layer;
a connection capping layer configured to cover side surfaces of the first holes and connect the inner capping layer to the outer capping layer, and form through-holes in the first holes; and
a buried capping layer disposed in the effective pixel region and filling the through-holes.

17. The image sensing device according to claim 16, wherein:
the inner capping layer, the outer capping layer, and the connection capping layer have a same thickness.

18. The image sensing device according to claim 12, wherein:
each of the first capping layer and the second capping layer includes an ultra-low-temperature oxide (ULTO) layer.

19. The image sensing device according to claim 12, wherein:
the first capping layer includes an ultra-low-temperature oxide (ULTO) layer; and
the second capping layer includes at least one of an aluminum oxide (Al₂O₃) layer, a hafnium oxide (HfO₂) layer, or a silicon nitride (SiN) layer.

20. The image sensing device according to claim 12, wherein:
the air layer extends to a position lower than a bottom surface of the first capping layer.
